(19) United States
(12) Patent Application Publication
(10) Pub. No.: US 2008/0088383 A1
(43) Pub. Date: Apr. 17, 2008

(54) Crystal oscillator circuit

(76) Inventor: Motoki Sakai, Kanagawa (JP)

Correspondence Address: MCDERMOTT WILL & EMERY LLP, 600 13TH STREET, NW, WASHINGTON, DC, 20005-3096, US

(21) Appl. No.: 11/907,740

(22) Filed: Oct. 17, 2007

(30) Foreign Application Priority Data
Oct. 17, 2006 (JP) P.2006-282790

(51) Int. Cl. H03B 5/36

(52) U.S. Cl. 331/116 FE

(57) ABSTRACT

The output part of a power circuit with a temperature characteristic 31 is connected to the power voltage of a CMOS inverter-type oscillator circuit 4 including a crystal vibrator. The power circuit with a temperature characteristic 31 includes an amplifier 2, a diode 20 and a resistor 11. The output end V2 of the amplifier 2 is connected to the anode of the diode 20. The cathode of the diode 20 is connected to the negative input end V3 of the amplifier 2 and one end of the resistor 11, and the other end of the resistor 11 is grounded. To the positive input end V1 of the amplifier 2 is connected a voltage source 1 with small VCC variations.

### BACKGROUND OF THE INVENTION

1. Field of the Invention

The present invention relates to a crystal oscillator circuit whose main application is a TCXO (Temperature Compensated Xtal Oscillator) and that outputs a stable oscillating frequency in a wide temperature range, features low power consumption and requires an excellent phase noise characteristic.

2. Description of the Related Art

A cell phone is requested to deliver a high speech quality and, as a TCXO (Temperature Compensated Xtal Oscillator), provide a very high frequency stability of ±0.5 to ±2.5 ppm or below in a wide temperature range and a now noise phase noise characteristic as well as lower power consumption.

The related art CMOS inverter-type crystal oscillator circuit will be described. FIG. 5 is an exemplary circuit configuration of a CMOS inverter-type crystal oscillator circuit in the related art.

In FIG. 5, a CMOS inverter-type crystal oscillator circuit 4 includes a crystal vibrator 41 and a feedback resistor 42 both ends of which are respectively connected to the input and output of a CMOS inverter 40. To the source voltage of the CMOS inverter-type oscillator circuit 4 is connected the output part of a power circuit that does not have a temperature characteristic (hereinafter referred to as the power circuit without a temperature characteristic) 30.

The power circuit without a temperature characteristic 30 includes an amplifier 2, a feedback resistor 10 and a resistor 11. The output end V2 of the amplifier 2 is connected to one end of the resistor 10. The other end of the feedback resistor 10 is connected to the negative input end V3 of the amplifier 2 and one end of the resistor 11, and the other end of the resistor 11 is grounded. To the positive input end V1 of the amplifier 2 is connected a voltage source 1 that is resistant to variations in the power source VCC using a band gap regulator or the like and shows small temperature variations. In this way, the related art crystal oscillator circuit shown in FIG. 4 includes a voltage source 1, a power circuit without a temperature characteristic 30, and a CMOS inverter-type oscillator circuit 4.

Operation of the CMOS inverter-type crystal oscillator circuit thus configured will be described.

In FIG. 5, a stable voltage with small temperature characteristic variations is supplied from the voltage source to the power circuit without a temperature characteristic 30. The output V2 of power circuit without a temperature characteristic 30 amplified by the feedback resistor 10 and the resistor 11 is used as the power voltage of the CMOS inverter-type oscillator circuit 4.

In this way, based on the assumption that the output of the power circuit 30 that is resistant to the voltage VCC and shows small temperature variations is used for the power voltage of the CMOS inverter-type oscillator circuit 4, a high frequency stability has been sought for that is required of a TCXO (for example, refer to JP-A-11-097932).

While the CMOS inverter-type crystal oscillator circuit using the power circuit 30 without a temperature characteristic as in the related art is resistant to variations in the voltage VCC, the CMOS inverter 40 in the oscillator circuit 4 has a threshold voltage VT having a temperature characteristic of −2 mV/° C. and thus large temperature variations occur in the oscillation characteristics of the oscillator circuit 4 such as the current consumption and a negative resistance. On top of the temperature characteristic of the threshold voltage VT, a variance of the threshold voltage VT itself produces a large variance of the oscillation characteristic.

Even when the voltage source 1 that is resistant to variations in the voltage VCC and shows small temperature variations is provided in a low-noise design, the voltage source 1 is amplified by the power circuit 30 and the voltage noise increases. Another problem is that the voltage noise worsens with the thermal noise generated in the feedback resistor 10 of the amplifier 2.

### SUMMARY OF THE INVENTION

The invention solves the above related art problems. An object of the invention is to provide a crystal oscillator circuit capable of dramatically improving variations in the current consumption or a negative resistance caused by the temperature variations in the threshold voltage VT of the oscillator circuit including a CMOS inverter. Another object of the invention is to provide a crystal oscillator circuit including the CMOS inverter capable of improving the characteristic variations caused by a variance of the threshold voltage VT of the crystal oscillator circuit and assuring a low noise design.

A crystal oscillator circuit according to the invention is characterized by comprising a CMOS inverter-type oscillator circuit including a crystal vibrator and a power circuit for supplying to the CMOS inverter-type oscillator circuit an output voltage having a temperature characteristic compensating for the temperature characteristic of the threshold voltage of the CMOS inverter-type oscillator circuit.

With this configuration, a power circuit is included for supplying to the CMOS inverter-type oscillator circuit an output voltage having a temperature characteristic compensating for the temperature characteristic of the threshold voltage of the CMOS inverter-type oscillator circuit. This makes it possible to dramatically improve the oscillation characteristic variations caused by the temperature characteristic of the threshold voltage of the CMOS inverter-type oscillator circuit.

A crystal oscillator circuit according to the invention is characterized in that the power circuit includes a voltage source for supplying a reference voltage to the power circuit.

A crystal oscillator circuit according to the invention is characterized in that the voltage source includes a band gap regulator.

A crystal oscillator circuit according to the invention is characterized by including a regulator circuit for regulating the output voltage of the power circuit.

With the above configuration, it is possible to select an optimum output voltage depending on the variance of the threshold voltage VT by using the regulator circuit. It is thus possible to dramatically improve the variations in the oscillation characteristic caused by the variance of the threshold voltage of the CMOS inverter-type oscillator circuit.

A crystal oscillator circuit according to the invention is characterized in that the power circuit includes: an amplifier for receiving the reference voltage at the positive input end and supplying an output voltage to the CMOS inverter-type oscillator circuit; a first diode whose anode is connected to the output end of the amplifier and whose cathode is connected to the negative input end of the amplifier; and a first resistor connected between the negative input end of the amplifier and a ground.

With this configuration, a first diode is used in the output part of the positive input end as means for providing a power circuit with temperature characteristic. This dramatically reduces the output voltage noise of a power circuit and thus improves a phase noise characteristic especially important for increasing the speech quality among the crystal oscillator circuit characteristics.

A crystal oscillator circuit according to the invention is characterized in that the power circuit includes: an amplifier for receiving the reference voltage at the positive input end and supplying an output voltage to the CMOS inverter-type oscillator circuit; a second diode whose anode is connected to the output end of the amplifier; a second resistor connected between the cathode of the second diode and the negative input end of the amplifier; a third resistor connected between the negative input end of the amplifier and a ground; and a regulator circuit for regulating the output voltage of the power circuit by regulating the resistance value of at least any one of the second resistor and the third resistor.

A crystal oscillator circuit according to the invention is characterized in that the power circuit includes: an amplifier for receiving the reference voltage at the positive input end and supplying an output voltage to the CMOS inverter-type oscillator circuit; a second resistor whose one end is connected to the output end of the amplifier; a second diode whose anode is connected to the other end of the second resistor and whose cathode is connected to the negative input end of the amplifier; a third resistor connected between the negative input end of the amplifier and a ground; and a regulator circuit for regulating the output voltage of the power circuit by regulating the resistance value of at least any one of the second resistor and the third resistor.

A crystal oscillator circuit according to the invention is characterized in that the first or second regulator circuit includes a storage device capable of writing and reading data.

The crystal oscillator circuit according to the invention comprises a power circuit for supplying to a CMOS inverter-type oscillator circuit an output voltage having a temperature characteristic compensating for the temperature characteristic of the threshold voltage of the CMOS inverter-type oscillator circuit. This makes it possible to dramatically improve the oscillation characteristic variations caused by the temperature characteristic of the threshold voltage of the CMOS inverter-type oscillator circuit.

With the crystal oscillator circuit according to the invention, it is possible to correct the variance of a threshold voltage by regulating the output voltage of a power circuit with a temperature characteristic. Further, with the crystal oscillator circuit according to the invention, it is possible to reduce the output voltage noise of a power circuit by using a diode in the output part of the power circuit and thus reduce a phase noise especially important among the crystal oscillator circuit characteristics.

### BRIEF DESCRIPTION OF THE DRAWINGS

FIG. 1 is a block diagram of a CMOS inverter-type crystal oscillator circuit according to Embodiment 1 of the invention.

FIG. 2 is a block diagram of a CMOS inverter-type crystal oscillator circuit according to Embodiment 2 of the invention.

FIG. 3(a) is an explanatory drawing that shows a temperature characteristic example of the current consumption of a crystal oscillator circuit in Embodiment 1.

FIG. 3(b) is an explanatory drawing that shows a temperature characteristic example of the current consumption of a crystal oscillator circuit in Embodiment 2.

FIG. 4 (a) is a block diagram of a CMOS inverter-type crystal oscillator circuit in which diodes are serially provided, according to the invention.

FIG. 4 (b) is a block diagram of a CMOS inverter-type crystal oscillator circuit in which power circuits are serially provided, according to the invention.

FIG. 5 is a block diagram of a related art CMOS inverter-type crystal oscillator circuit.

### DESCRIPTION OF THE PREFERRED EMBODIMENTS

### Embodiment 1

A first embodiment of the invention will be described referring to drawings. FIG. 1 shows the configuration of a CMOS inverter-type crystal oscillator circuit according to the first embodiment. The CMOS inverter-type crystal oscillator circuit shown in FIG. 1 comprises a reference voltage source 1, a power circuit that has a temperature characteristic (hereinafter referred to as the power circuit with a temperature characteristic) 31, and a CMOS inverter-type oscillator circuit 4. In FIG. 1, the CMOS inverter-type oscillator circuit 4 includes a crystal vibrator 41 and a feedback resistor 42 both ends of which are respectively connected to the input and output of a CMOS inverter 40, and a buffer amplifier (not shown) in an output stage. The power voltage of the CMOS inverter-type oscillator circuit 4 is connected to the output end V2 of the power circuit with a temperature characteristic 31.

The power circuit with a temperature characteristic 31 includes an amplifier 2, a diode 20, and a resistor 11. The amplifier 2 is a buffer having an amplification factor of 1. The diode 20 has a temperature characteristic compensating for the temperature characteristic of a CMOS inverter 40. In the power circuit with a temperature characteristic 31, the output end V2 of the amplifier 2 is connected to the anode of the diode 20, the cathode of the diode 20 is connected to the negative input end V3 of the amplifier 2 and one end of the resistor 11, and the other end of the resistor 11 is grounded. To the positive input end V1 of the amplifier 2 is connected a stable voltage source 1 that is resistant to variations in a voltage source VCC. The voltage source 1 uses a stable reference voltage source such as a band gap regulator that has small temperature characteristic variations and is resistant to variations in the voltage source VCC. The crystal oscillator circuit according to the first embodiment shown in FIG. 1 has such a configuration.

Operation of the crystal oscillator circuit according to the first embodiment having such a configuration will be described.

In FIG. 1, a stable reference voltage with small temperature characteristic variations is supplied from the voltage source as V1 to the input end of the power circuit with a temperature characteristic 31. The output V2 of the power circuit with a temperature characteristic 31 buffered by the diode 20 and the resistor 11 is used as the power voltage of the CMOS inverter-type oscillator circuit 4.

The electrical characteristic of the CMOS inverter 40 in the CMOS inverter-type oscillator circuit 4 is represented by a linear region in a large signal input characteristic. A relation between a drain current (hereinafter referred to as Id), a gate-source voltage (hereinafter referred to as Vgs), and a threshold voltage (hereinafter referred to as Vt) is generally expressed as:

Id=K′W/L[(Vgs−Vt)̂2−0.5*Vdŝ2][1+λVds] (1)

In Expression (1), K′=μnCOX-(for n-type MbS), μpCOX-(for p-type MOS), COX-: Gate oxide film capacitance, μn: mobility of electrons, μp: Mobility of positive holes, W: Gate width of MOS, L: Gate length of MOS, and λ: Channel length change factor.

From Expression (1), it is understood that, in case the value of the difference (Vgs−Vt) between the gate-source voltage Vgs and the threshold voltage Vt is constant, the drain current Id is constant, that is, the current consumption of the CMOS inverter-type oscillator circuit 4 is constant.

The threshold voltage VT generally has a temperature characteristic of −2 mV/° C. so that the gate-source voltage Vgs also requires an equivalent temperature characteristic. The most effective method to attain this is to provide the power voltage of the CMOS inverter-type oscillator circuit 4 with a temperature characteristic equivalent to that of the threshold voltage VT. In the first embodiment, this is made possible by adding the diode 20 having a temperature characteristic of −2 mV/° C. in the output part of the power circuit with a temperature characteristic 31.

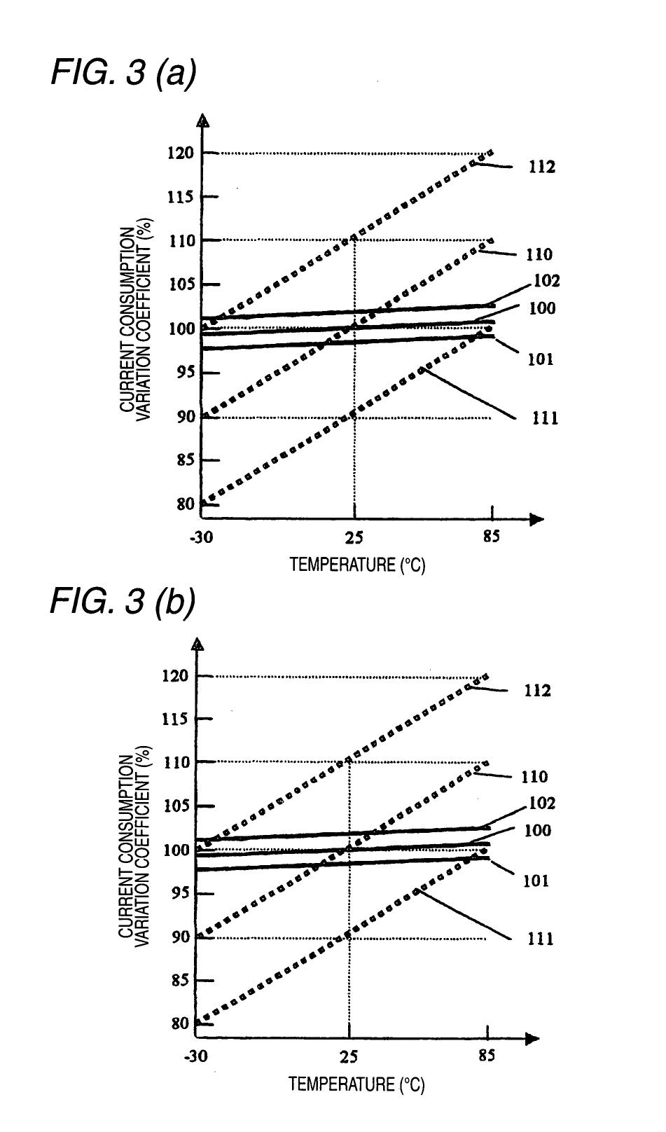

FIG. 3(a) is a graph showing the temperature variation coefficient of the current consumption of the oscillator circuit in Embodiment 1. In FIG. 3, a straight line 110 shows an example of temperature characteristic in Embodiment 1. For comparison, an example of temperature characteristic in the related art is shown as a dotted line 110. From FIG. 3(a), it is understood that, while the current consumption of an oscillator circuit has substantially changed with temperature variations in the related art, variations in the temperature characteristic is suppressed and the current consumption is kept almost constant irrespective of the temperature in Embodiment 1.

By compensating for the temperature characteristic of −2 mV/° C. of the threshold voltage VT of the CMOS inverter 40 in the oscillator circuit 4 with the temperature characteristic of −2 mV/° C. of the diode 20, it is possible to dramatically reduce temperature characteristic variations in the current and negative resistance of the oscillator 4, a difficult approach in the related art systems.

The power circuit with a temperature characteristic 31 using the diode 20 is a simple buffer having an amplification factor of 1. Assuming that the voltage noises of the voltages V1, V2 and V3 at corresponding terminals are respectively NV1, NV2 and NV3, the voltage noises are equal:

NV1=NV2=NV3 (2)

While the voltage noise increases by the amount the voltage is amplified in the amplifier 2 in the related art, the voltage noise is not amplified in Embodiment 1. This dramatically reduces the voltage noise.

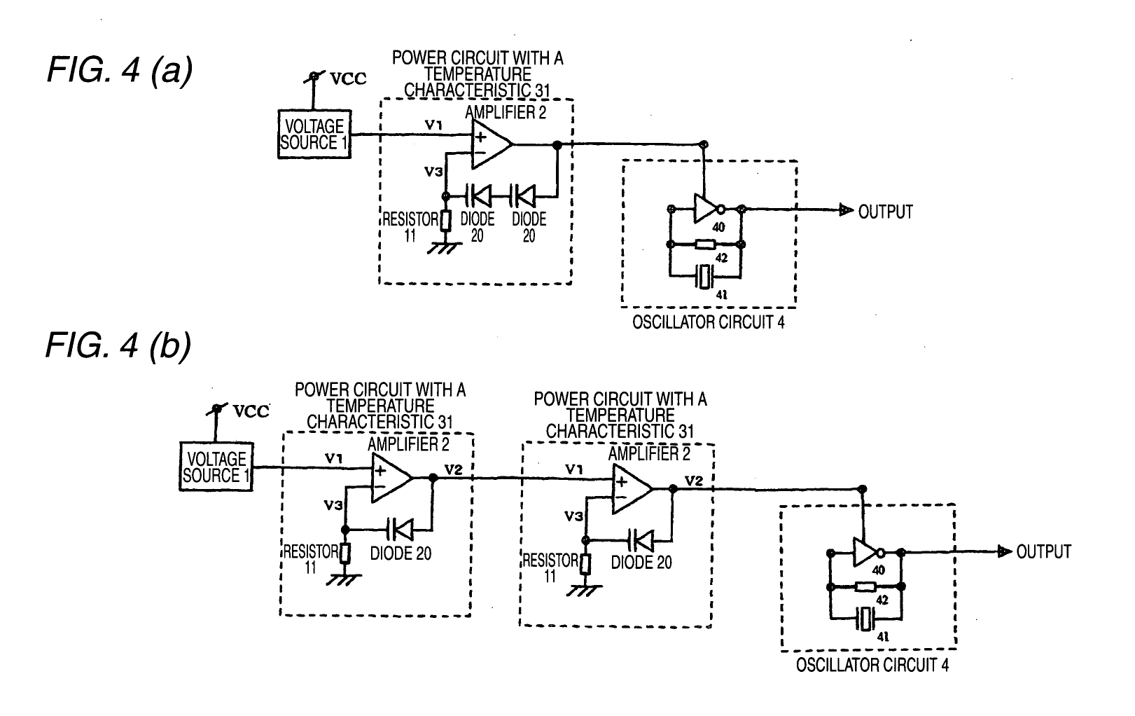

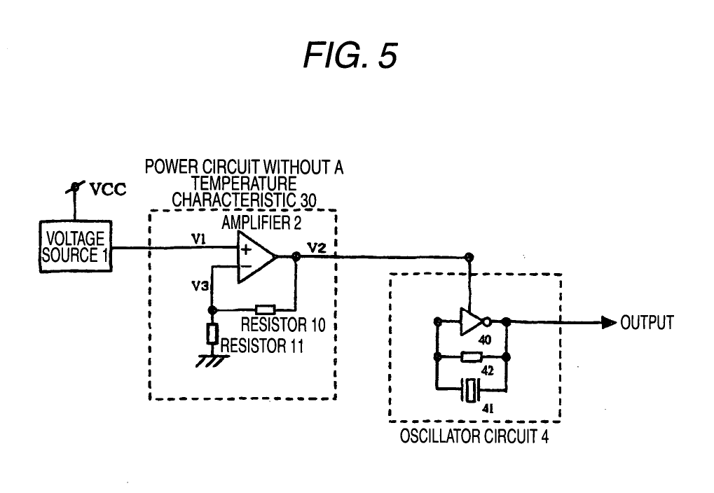

While the thermal noise from the feedback resistor 10 (refer to FIG. 4) is a factor that worsens the voltage noise in the related art, the resistor 10 is replaced with the diode 20 and the current flowing through the diode 20 is reduced and optimized to reduce a shot noise, thereby reducing the noise from the amplifier 2 than in the related art.

As mentioned above, according to the first embodiment, it is possible to reduce variations in the temperature characteristics such as the current consumption and negative resistance of the oscillator circuit 4, a difficult approach in the related art systems. Moreover, the voltage noise from a voltage circuit is dramatically reduced thus reducing the phase noise especially important among the crystal oscillator circuit characteristics.

### Embodiment 2

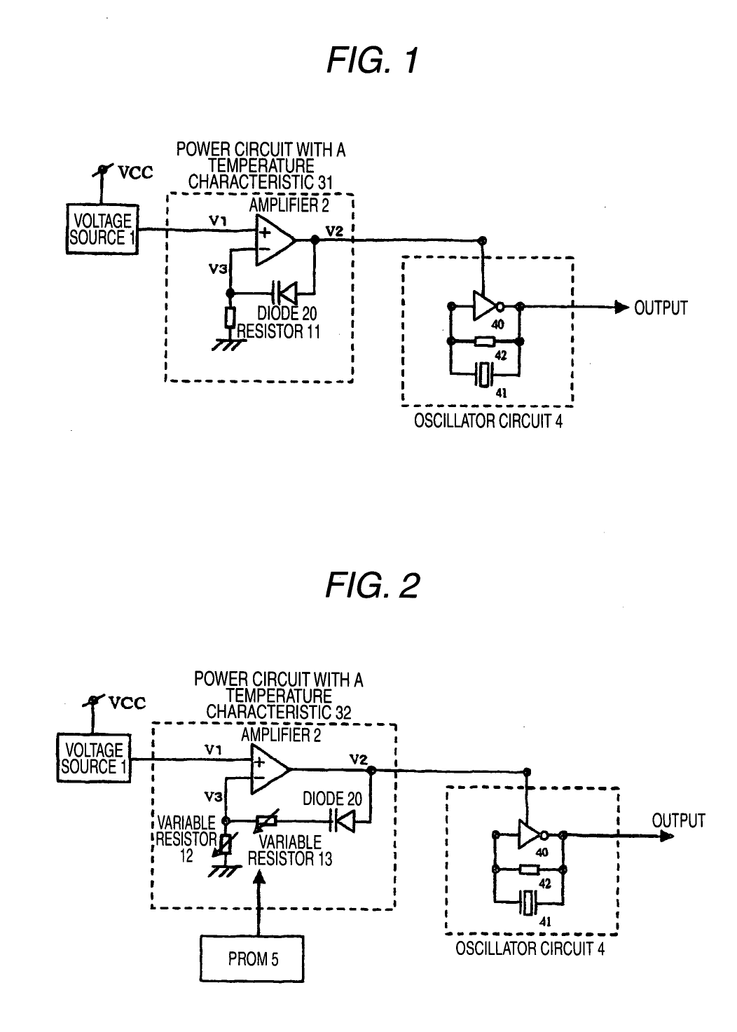

A second embodiment of the invention will be described referring to drawings. FIG. 2 shows the configuration of a CMOS inverter-type crystal oscillator circuit according to the second embodiment. In the description that follows, a member corresponding to the already described member is give a same sign and detailed description is omitted.

In the second embodiment, the power voltage of a CMOS inverter-type oscillator circuit 4 is connected to the output end V2 of a power circuit with a temperature characteristic 31. The power circuit with a temperature characteristic 31 includes an amplifier 2, a diode 20, a variable resistor 12, and a variable resistor 13.

The output end V2 of the amplifier 2 is connected to the anode of the diode 20. The cathode of the diode 20 is connected to one end of the variable resistor 13. The other end of the variable resistor 13 is connected to the negative input end V3 of the amplifier 2 and one end of the variable resistor 12. The other end of the variable resistor 12 is grounded.

To the positive input end V1 of the amplifier 2 is connected a stable voltage source 1 that is resistant to variation in a voltage VCC. The variable resistors 12, 13 are connected to a regulator circuit (PROM) 5 for regulating the output voltage of a power circuit with a temperature characteristic 32 by changing the resistance values of the variable resistors 12, 13. The crystal oscillator circuit according to the second embodiment shown in FIG. 2 has such a configuration.

Operation of the crystal oscillator circuit according to the second embodiment having such a configuration will be described.

Same as the power circuit with a temperature characteristic 31 described in Embodiment 1, the power circuit with a temperature characteristic 32 according to Embodiment 2 has an effect of reducing the variations in the temperature characteristic of the threshold voltage VT of the oscillator circuit 4 and an effect of reducing the voltage noise of the power circuit with a temperature characteristic 32. Further, in Embodiment 2, the regulator circuit (PROM) 5 can arbitrarily regulate the output voltage V2 by changing the resistance value of the variable resistor 12 or 13. It is thus possible to select the optimum output voltage V2 in accordance with the variance of the threshold voltage VT of the CMOS inverter 40 in the oscillator 4.

Thus, in the relation expression (1), the gate-source voltage and the threshold voltage (Vgs−Vt) is kept constant and the drain current Id is constant. In other words, the current consumption of the CMOS inverter-type oscillator circuit 4 is kept constant and it is possible to correct variations in the oscillation characteristics such as a negative resistance as well as the current consumption.

FIG. 3(b) is a graph showing the variation coefficient of the current consumption with respect to the variance of the threshold voltage VT in the oscillator circuit in Embodiment 2.

In FIG. 3(b), dotted lines 110 to 112 show examples of temperature characteristic in the variance of VT in the related art. Straight lines 110, 111, and 112 respectively show the current consumption variation coefficient for the threshold voltage Vt(typ), threshold voltage Vt(max) and threshold voltage Vt(min).

Straight lines 100 to 102 show examples of temperature characteristic obtained after the power voltage of the oscillator circuit is regulated in accordance with the variance of the threshold voltage VT in Embodiment 2. The straight lines 100, 101, and 102 respectively show the current consumption variation coefficient for the threshold voltage Vt(typ), threshold voltage Vt(max) and threshold voltage Vt(min).

From FIG. 3(b), it is understood that, while the current consumption of an oscillator circuit has substantially changed with temperature variations and the variance of the threshold voltage VT in the related art, variations in the temperature characteristic is suppressed despite the variance of the threshold voltage VT and the current consumption is kept almost constant irrespective of the temperature in Embodiment 2.

As mentioned above, according to Embodiment 2, unlike the large variations in the oscillation characteristic caused by the variance of the threshold voltage VT of the oscillator circuit as in the related art, the output voltage V2 is selected in accordance with the variance of the threshold voltage VT of the oscillator circuit thus allowing correction of the variance of the current consumption of a crystal oscillator circuit and oscillation characteristics such as a negative resistance.

While the variable resistors 12 and 13 are used in the power circuit with a temperature characteristic 31, either the variable resistor 12 or 13 may be a fixed resistor. In case both are variable resistors, the resistance values of the variable resistors 12 and 13 may be varied by way of current variable regulation and voltage variable regulation respectively in order to obtain a solution that best reduces the voltage noise as well as best regulate the output voltage.

Methods for regulating the resistance values of the variable resistors 12, 13 by using the regulator circuit (PROM) 5 includes a method for connecting multiple resistors serially or in parallel and changing the resistance values by directly making individual resistors short/open with a switch and a method for regulating the resistance values by selecting between plural tap switches at the midpoint of a resistor body such as a resistor control knob. Control of these switches is made by overwriting the data of the regulator circuit (PROM) 5.

As described above, with the crystal oscillator circuit according to this embodiment, the problem of variations in the characteristics such as the current consumption and a negative resistance due to the temperature characteristic or variance of the CMOS threshold voltage VT of a CMOS inverter-type oscillator circuit is solved by using the output of a poser circuit with a temperature characteristic including a diode having a temperature characteristic equivalent to that of the CMOS threshold voltage VT of an oscillator circuit. It is thus possible to compensate for temperature characteristic variations of the CMOS inverter-type oscillator circuit.

Further, it is possible to correct the variance of the CMOS threshold voltage VT of an oscillator circuit by regulating the output voltage of a power circuit with a temperature characteristic. By using a diode in the output part of the power circuit, the output voltage noise of the power circuit may be reduced in design thus reducing the phase noise especially important among the crystal oscillator circuit characteristics.

In addition, although the threshold voltage VT of the CMOS inverter is −2 mV/° C. in the first and second embodiments, for instance, in case that the threshold voltage VT of the CMOS inverter is −4 mV/° C., it is possible to provide the power voltage of the CMOS inverter-type oscillator circuit with a temperature characteristic of −4 mV/° C. equivalent to that of the threshold voltage VT, by serially providing two diodes 20 each having a temperature characteristic of −2 mV/° C. as shown in FIG. 4(a), or by serially providing two of the power circuits 31 each having a temperature characteristic of −2 mV/° C. as shown in FIG. 4 (b), in the first embodiment. As well, this changes, needless to say, can be applicable to the second embodiment.

Further, although the diode is used for compensating for the temperature characteristic of the threshold voltage of the CMOS inverter-type oscillator circuit in the above-described embodiments, other elements such as a register having the temperature characteristic compensating for the temperature characteristic of the threshold voltage of the CMOS inverter-type oscillator circuit without noise characteristics may be used.

Further, a buffer circuit may be provided between the power circuit with a temperature characteristic and the CMOS inverter-type oscillator circuit.

The invention has an effect of reducing the temperature characteristic variations of a CMOS inverter-type oscillator circuit by using, as the power source of an oscillator circuit, a power circuit having the temperature characteristic of a diode having a temperature characteristic equivalent to that of the CMOS threshold voltage VT of a CMOS inverter-type oscillator circuit. The invention has a main application of a TCXO (Temperature Compensated Xtal Oscillator) and is useful for a crystal oscillator circuit that outputs a stable oscillating frequency in a wide temperature range, features low power consumption and requires an excellent phase noise characteristic.

1. A crystal oscillator circuit, comprising:
a CMOS inverter-type oscillator circuit including a crystal vibrator; and
a power circuit for supplying to said CMOS inverter-type oscillator circuit an output voltage having a temperature characteristic compensating for the temperature characteristic of the threshold voltage of said CMOS inverter-type oscillator circuit.

2. The crystal oscillator circuit according to claim 1, wherein said power circuit includes a voltage source for supplying a reference voltage to said power circuit.

3. The crystal oscillator circuit according to claim 2, wherein said voltage source includes a band gap regulator.

4. The crystal oscillator circuit according to claim 1, further comprising:
a regulator circuit for regulating the output voltage of said power circuit.

5. The crystal oscillator circuit according to claim 2,
wherein said power circuit includes:
an amplifier for receiving said reference voltage at the positive input end and supplying an output voltage to said CMOS inverter-type oscillator circuit;
a first diode whose anode is connected to the output end of said amplifier and whose cathode is connected to the negative input end of said amplifier; and
a first resistor connected between the negative input end of said amplifier and a ground.

6. The crystal oscillator circuit according to claim 2,
wherein said power circuit includes:
an amplifier for receiving said reference voltage at the positive input end and supplying an output voltage to said CMOS inverter-type oscillator circuit;
a second diode whose anode is connected to the output end of said amplifier;
a second resistor connected between the cathode of said second diode and the negative input end of said amplifier;
a third resistor connected between the negative input end of said amplifier and a ground; and
a regulator circuit for regulating the output voltage of said power circuit by regulating the resistance value of at least any one of said second resistor and said third resistor.

7. The crystal oscillator circuit according to claim 2,
wherein said power circuit includes:
an amplifier for receiving said reference voltage at the positive input end and supplying an output voltage to said CMOS inverter-type oscillator circuit;
a second resistor whose one end is connected to the output end of said amplifier;
a second diode whose anode is connected to the other end of said second resistor and whose cathode is connected to the negative input end of said amplifier;
a third resistor connected between the negative input end of said amplifier and a ground; and
a regulator circuit for regulating the output voltage of said power circuit by regulating the resistance value of at least any one of said second resistor and said third resistor.

8. The crystal oscillator circuit according to claim 4 characterized in that regulator circuit includes a storage device capable of writing and reading data.

9. The crystal oscillator circuit according to claim 6 characterized in that regulator circuit includes a storage device capable of writing and reading data.

10. The crystal oscillator circuit according to claim 7 characterized in that regulator circuit includes a storage device capable of writing and reading data.
